(19) United States
(12) Patent Application Publication
(10) Pub. No.: US 2011/0012088 A1
(43) Pub. Date: Jan. 20, 2011

(54) OPTOELECTRONIC SEMICONDUCTOR BODY WITH A TUNNEL JUNCTION AND METHOD FOR PRODUCING SUCH A SEMICONDUCTOR BODY

(75) Inventors: Martin Strassburg, Tegernheim (DE); Lutz Hoeppel, Alteglofsheim (DE); Matthias Sabathil, Regensburg (DE)

Correspondence Address: IP GROUP OF DLA PIPER LLP (US), ONE LIBERTY PLACE, 1650 MARKET ST, SUITE 4900, PHILADELPHIA, PA, 19103, US

(73) Assignee: OSRAM OPTO SEMICONDUCTORS GMBH, Regensburg (DE)

(21) Appl. No.: 12/919,532

(22) PCT Filed: Feb. 26, 2009
(86) PCT No.: PCT/DE09/00282

§ 371 Date: Oct. 4, 2010

(30) Foreign Application Priority Data
Feb. 29, 2008 (DE) 10 2008 011 849.4
Jun. 12, 2008 (DE) 10 2008 028 036.4

(51) Int. Cl. H01L 33/04; H01L 33/00

(52) U.S. Cl. 257/13; 438/45; 257/E33.008; 257/E29.005

(57) ABSTRACT

An optoelectronic semiconductor body includes an epitaxial semiconductor layer sequence including a tunnel junction including an intermediate layer between an n-type tunnel junction layer and a p-type tunnel junction layer, wherein the intermediate layer has an n-barrier layer facing the n-type tunnel junction layer, a p-barrier layer facing the p-type tunnel junction layer, and a middle layer with a material composition differing from material compositions of the n-barrier layer and the p-barrier layer; and an active layer that emits electromagnetic radiation.

### RELATED APPLICATIONS

This is a §371 of International Application No. PCT/DE2009/000282, with an international filing date of Feb. 26, 2009 (WO 2009/106070 A1, published Sep. 3, 2009), which is based on German Patent Application Nos. 10 2008 011 849.4, filed Feb. 29, 2008, and 10 2008 028 036.4, filed Jun. 12, 2008, the subject matter of which is incorporated by reference.

### TECHNICAL FIELD

This disclosure relates to an optoelectronic semiconductor body with a tunnel junction and a method for producing such a semiconductor body.

### BACKGROUND

An optoelectronic semiconductor body with a tunnel junction is disclosed in WO 2007/012327 A1, for example. However, it could be helpful to provide an optoelectronic semiconductor body with an improved tunnel junction.

### SUMMARY

We provide an optoelectronic semiconductor body including an epitaxial semiconductor layer sequence including a tunnel junction including an intermediate layer between an n-type tunnel junction layer and a p-type tunnel junction layer, wherein the intermediate layer has an n-barrier layer facing the n-type tunnel junction layer, a p-barrier layer facing the p-type tunnel junction layer, and a middle layer with a material composition differing from material compositions of the n-barrier layer and the p-barrier layer; and an active layer that emits electromagnetic radiation.

We also provide an optoelectronic semiconductor body including an epitaxial semiconductor layer sequence including a tunnel junction including an intermediate layer between an n-type tunnel junction layer and a p-type tunnel junction layer, wherein the intermediate layer is provided with imperfections in a targeted manner; and an active layer that emits electromagnetic radiation.

We further provide a method for producing an optoelectronic semiconductor body including an epitaxial semiconductor layer sequence including a tunnel junction including an n-type tunnel junction layer, an intermediate layer and a p-type tunnel junction layer; and an active layer that emits electromagnetic radiation, including producing the intermediate layer by epitaxially depositing a semiconductor material and providing imperfections in the intermediate layer in a targeted manner in selected locations.

### BRIEF DESCRIPTION OF THE DRAWINGS

Further advantages and advantageous configurations of the optoelectronic semiconductor body and of the method will become apparent from the following examples illustrated in connection with the figures.

In the figures:

FIG. 1 shows a schematic sectional illustration of an optoelectronic semiconductor body in accordance with a first example;

FIG. 2 shows a schematic sectional illustration of an optoelectronic semiconductor body in accordance with a second example;

FIG. 3 shows a schematic sectional illustration of an optoelectronic semiconductor body in accordance with a third example;

FIG. 4 shows a schematic illustration of the band structure and of the charge carrier density in the case of the semiconductor body in accordance with the first example;

FIG. 5A shows a schematic illustration of the band structure in the case of the semiconductor body in accordance with the second example;

FIG. 5B shows a schematic illustration of the charge carrier density in the case of the semiconductor body in accordance with the second example; and

FIG. 6 shows a schematic illustration of the band structure in the case of the semiconductor body in accordance with the third example.

### DETAILED DESCRIPTION

We provide an optoelectronic semiconductor body and a method for producing an optoelectronic semiconductor body. An optoelectronic semiconductor body comprising an epitaxial semiconductor layer sequence is particularly specified. The epitaxial semiconductor layer sequence has a tunnel junction and an active layer provided for the emission of electromagnetic radiation. The tunnel junction contains an intermediate layer between an n-type tunnel junction layer and a p-type tunnel junction layer.

The term “tunnel junction layer” is used to differentiate from the remaining semiconductor layers of the semiconductor body and means that the n-conducting or p-conducting layer thus designated is contained in that region of the semiconductor layer sequence which is designated as the tunnel junction. In particular, with the semiconductor layers contained in the tunnel junction, that is to say at least by means of the n-type tunnel junction layer, the p-type tunnel junction layer and also by the intermediate layer, an electrical potential profile suitable for the tunneling of charge carriers is brought about.

In one example, the intermediate layer has an n-barrier layer facing the n-type tunnel junction layer, a p-barrier layer facing the p-type tunnel junction layer, and a middle layer. The material composition of the middle layer differs from the material composition of the n-barrier layer and from the material composition of the p-barrier layer.

In one configuration, the intermediate layer, that is to say in particular the n-barrier layer, the middle layer and the p-barrier layer, comprises a semiconductor material containing a first and a second component. Preferably, the proportion of the first component is lower in the middle layer than in the n-barrier layer and/or in the p-barrier layer. In one development, the first component contains aluminum or the first component consists of aluminum. In another development, the second component contains at least one of the following elements: In, Ga, N, P. By way of example, the intermediate layer comprises the semiconductor material AlInGaN, and the first component is aluminum and the second component is InGaN.

The phrase “comprises the semiconductor material AlInGaN” means that the intermediate layer, preferably also the active layer, comprises or consists of a nitride compound semiconductor material, preferably AlₙInₘGa₁₋ₙ₋ₘN, where 0≦n≦1, 0≦m≦1 and n+m≦1. This material need not necessarily have a mathematically exact composition according to the above formula. Rather, it can comprise, for example, one or more dopants and also additional constituents. For the sake of simplicity, however, the above formula only includes the essential constituents of the crystal lattice (Al, In, Ga, N), even if these can be replaced and/or supplemented in part by small amounts of further substances.

In a further configuration, the proportion of the first component, that is to say the aluminum proportion, for example, is less than or equal to 20 percent in the middle layer. In the n-barrier layer and/or the p-barrier layer, the proportion of the first component is, in particular, greater than or equal to 20 percent. By way of example, the following holds true in the case of this configuration and the material AlₙInₘGa₁₋ₙ₋ₘN or AlₙInₘGa₁₋ₙ₋ₘP for the aluminum proportion n in the middle layer: n≦0.2 and in particular in the n-barrier layer and/or the p-barrier layer: n>0.2.

In one advantageous configuration, a layer thickness of the n-barrier layer and/or a layer thickness of the p-barrier layer is less than or equal to 2 nm. For example, it lies between 0.3 nm and 2 nm, in particular between 0.5 nm and 1 nm, in each case inclusive of the limits. In one advantageous configuration, a layer thickness of the middle layer has a value of between 1 nm and 8 nm, preferably between 2 nm and 4 nm, in each case inclusive of the limits.

By means of the intermediate layer having an n-barrier layer, a p-barrier layer and a middle layer, the material composition of which differs from the material composition of the n-barrier layer and/or of the p-barrier layer, improved electronic properties of the tunnel junction can be obtained.

By way of example, a diffusion of an n-type dopant from the n-type tunnel junction layer in the direction of the p-type tunnel junction layer and/or a diffusion of a p-type dopant from the p-type tunnel junction layer in the direction of the n-type tunnel junction layer are/is reduced by the n-barrier layer and/or by the p-barrier layer. Consequently, the risk of compensation of acceptors and donors which adversely influences the tunnel properties is reduced by the n-barrier layer and/or the p-barrier layer. The middle layer has in particular, for example, on account of the smaller proportion of the first component of the semiconductor material, a smaller band gap than the n-barrier layer and/or the p-barrier layer. A particularly high probability of tunneling of the charge carriers through the intermediate layer is advantageously obtained.

We discovered that, in the case of an intermediate layer comprising an n-barrier layer and/or a p-barrier layer, the layer thickness of which is, in particular, less than or equal to 2 nm, and comprising a middle layer of different material composition, strong polarization charges can be generated, whereby a particularly high charge carrier density can be brought about in the n-type tunnel junction layer and/or the p-type tunnel junction layer.

A high concentration of electrons in the n-type tunnel junction layer and/or of holes in the p-type tunnel junction layer can advantageously be obtained. The n-type tunnel junction layer and/or the p-type tunnel junction layer advantageously have/has, in particular, a particularly high transverse conductivity, with the result that particularly good lateral current spreading can be obtained. A particularly homogeneous distribution of the charge carriers laterally can advantageously be obtained. The area available to the charge carriers for tunnel junctions is therefore particularly large. A tunnel junction having a particularly low electrical resistance and an optoelectronic semiconductor body having a particularly low forward voltage can thus be obtained.

In a further example, the intermediate layer between the n-type tunnel junction layer and the p-type tunnel junction layer of the tunnel junction is provided with imperfections in a targeted manner. If the intermediate layer has a p-barrier layer, a middle layer and an n-barrier layer, in one configuration, the intermediate layer is provided with the imperfections in a targeted manner in the region of the middle layer.

By means of the imperfections, energetic states within the band gap are generated in the region of the intermediate layer which is provided with the imperfections. By means of these additional states, it is possible to increase the tunneling probability for charge carriers through the tunnel junction, with the result that an increased transfer rate of electrons and/or holes through the intermediate layer can be obtained. The additional states act, in particular, as so-called “tunneling centers.”

The imperfections are formed, for example, at least in part by defects of a semiconductor material of the intermediate layer. In particular, a defect density, that is to say the number of defects per volume, is increased in that region of the intermediate layer which is purposefully provided with imperfections by comparison with a region of the intermediate layer which succeeds the region purposefully provided with imperfections, and/or by comparison with a region of the intermediate layer which precedes the region purposefully provided with imperfections. By way of example, the defect density in the region provided with imperfections is at least twice as high, preferably at least five times as high, and in particular at least ten times as high, as that in the preceding and/or succeeding region of the intermediate layer.

In one configuration, the defect density in the region provided with imperfections has a value of greater than or equal to 10¹⁵ cm⁻³, preferably of greater than or equal to 10¹⁶ cm⁻³. For example, it has a value of 10¹⁷ cm⁻³ or more. In one configuration, the region provided with imperfections in a targeted manner and the region of the intermediate layer that succeeds and/or precedes it have the same material composition. In one configuration, in addition to the region provided with imperfections in a targeted manner, the region of the intermediate layer that precedes it and/or the region of the intermediate layer that succeeds it, having a lower defect density, are also contained in the middle layer between the n-barrier layer and the p-barrier layer.

In another configuration, the imperfections are formed at least in part by impurity atoms. The term “impurity atoms” denotes in particular atoms and/or ions which, in the semiconductor material of the intermediate layer, are usually not used either as main constituent (for instance Al, Ga, In or N ions in the semiconductor material AlInGaN) or as p-type dopant or n-type dopant.

It is advantageous if the energetic position of the additional states brought about by the imperfections is situated approximately in the center of the band gap. Such states are also called deep imperfections or “midgap states.” For this purpose, in the case of imperfections formed by impurity atoms, in particular metals, transition metals and/or rare earths are suitable as impurity atoms. By way of example, chromium, iron and/or manganese atoms can be used as impurity atoms. Pt atoms are also suitable as impurity atoms, for example. In contrast thereto, n-type dopants such as silicon and p-type dopants such as magnesium generally generate states which do not lie in the center of the band gap, but rather near to a band edge.

The impurity atoms can be incorporated into the crystal lattice of the semiconductor material of the intermediate layer, for example as substitution atoms and/or as interstitial atoms. As an alternative or in addition, the impurity atoms can also be contained as a layer in the intermediate layer. The layer of impurity atoms is preferably not closed. Rather, it has, in particular, openings pervaded by the semiconductor material of the intermediate layer. To put it another way, the semiconductor material of the intermediate layer runs through the openings in the layer of impurity atoms from the n-type side of the tunnel junction to the p-type side of the tunnel junction.

In one configuration, the impurity atoms contained in the region of the intermediate layer that is provided with imperfections in a targeted manner are present there in a concentration of between 10¹⁵ l/cm³ and 10¹⁹ l/cm³, inclusive of the limits. At a higher concentration of the impurity atoms, there is the risk of the quality of the semiconductor material being reduced. The tunneling current increases, in particular, more than proportionally with concentrations of the impurity atoms.

In one configuration, an edge region of the intermediate layer that is adjacent to the n-type tunnel junction layer and/or an edge region of the intermediate layer that is adjacent to the p-type tunnel junction layer are/is free of the imperfections introduced in a targeted manner. In the case of a semiconductor body whose intermediate layer contains an n-barrier layer, a middle layer and a p-barrier layer, in particular an edge region of the middle layer that is adjacent to the n-barrier layer and/or an edge region of the middle layer that is adjacent to the p-barrier layer are/is free of the imperfections introduced in a targeted manner. In a further configuration, the intermediate layer is provided with the imperfections approximately centrally between the n-type channel junction layer and the p-type channel junction layer. Such an extent and position of the imperfections is advantageous for the crystal quality of the intermediate layer.

In one configuration of the semiconductor body, the intermediate layer is nominally undoped. In another configuration, the intermediate layer is p-doped at least in places. In one development, the middle layer is p-doped. “Nominally undoped” means that the concentration of an n-type dopant and of a p-type dopant is at most 0.1 times as high, preferably at most 0.05 times as high, and in particular at most 0.01 times as high, as the concentration of the n-type dopant and of the p-type dopant in an n-doped and p-doped layer, respectively. By way of example, the concentration of the n-type dopant and p-type dopant, respectively, in the nominally undoped layer is less than or equal to 1×10¹⁸ atoms/cm³, preferably less than or equal to 5×10¹⁷ atoms/cm³, and in particular it is less than or equal to 1×10¹⁷ atoms/cm³.

In one configuration, the n-type tunnel junction layer and/or the p-type tunnel junction layer are embodied as a superlattice of alternating layers. By way of example, an InGaN/GaN superlattice is involved. With such a superlattice, it is possible to obtain a further increase in the charge carrier concentration in the n-type tunnel junction layer and/or the p-type tunnel junction layer, respectively. The lateral current spreading and the tunneling rate through the tunnel junction can thus be increased further.

In one expedient configuration, the epitaxial semiconductor layer sequence of the optoelectronic semiconductor body has an n-conducting layer, the tunnel junction, a p-conducting layer, the active layer and a further n-conducting layer in this order.

In another configuration, the epitaxial semiconductor layer sequence is based on a III/V compound semiconductor material, for example, on the semiconductor material AlInGaN. A III/V compound semiconductor material comprises at least one element from the third main group, such as, for example, B, Al, Ga, In, and an element from the fifth main group, such as, for example, N, P, As. In particular, the term “III/V compound semiconductor material” encompasses the group of the binary, ternary or quaternary compounds which contain at least one element from the third main group and at least one element from the fifth main group, for example, AlInGaN or AlInGaP. Such a binary, ternary or quaternary compound can additionally comprise, for example, one or more dopants and additional constituents.

In a method for producing an optoelectronic semiconductor body comprising an epitaxial semiconductor layer sequence having a tunnel junction and an active layer provided for the emission of electromagnetic radiation, wherein the tunnel junction has an n-type tunnel junction layer, an intermediate layer and a p-type tunnel junction layer, for producing the intermediate layer, a semiconductor material is deposited epitaxially, in particular in an epitaxy reactor. The semiconductor material of the intermediate layer is provided with imperfections in a targeted manner at least in places.

In one configuration, the process of provision with imperfections comprises introducing defects into the semiconductor material. By way of example, during the deposition of the semiconductor material in the epitaxy reactor, hydrogen gas is conducted into the epitaxy reactor at least at times for introducing the defects.

In one configuration, the amount of hydrogen gas introduced corresponds to an amount of, inclusive, 0.1% to 50% of that amount of hydrogen gas which is provided for the growth of silicon-doped gallium nitride (GaN:Si) with trimethylgallium (TMGa) as precursor in the epitaxy reactor. The amount of hydrogen provided for the growth of GaN:Si with TMGa as precursor is generally specified by the manufacturer of the epitaxy reactor and thus known in principle to those skilled in the art. In a further configuration, the hydrogen gas is conducted into the epitaxy reactor in an amount of between 0.1 standard liter per minute (slpm) and 20 slpm, preferably between 1 slpm and 10 slpm, in particular between 2 slpm and 5 slpm, in each case inclusive of the limits. In a further configuration, the hydrogen gas is conducted into the epitaxy reactor in an amount of six standard cubic centimeters per minute (6 sccm) or more. The hydrogen gas is preferably introduced only over a short period of time, for example of ten minutes or less, preferably of two minutes or less, and particularly preferably of one minute or less.

In another configuration of the method, during the deposition of the semiconductor material in the epitaxy reactor, a process temperature and/or a pressure in the epitaxy reactor are/is altered for introducing the defects. By way of example, the temperature is changed at a rate of greater than or equal to 60° C. per minute and/or the pressure is changed at a rate of greater than or equal to 100 mbar per minute. The change can take place in steps or continuously, as a so-called temperature and/or pressure ramp. In one development, the temporal duration of the temperature and/or pressure change is 120 seconds or less.

In another configuration, the intermediate layer is alternatively or additionally provided with imperfections by impurity atoms being introduced into the intermediate layer. By way of example, the impurity atoms and the semiconductor material are deposited at identical times, for instance by the sources that provide the semiconductor material and the impurity atoms being operated simultaneously at times. In this way, in one configuration, the impurity atoms are incorporated into the crystal lattice of the semiconductor material.

As an alternative, the semiconductor material is first deposited for forming a first part of the intermediate layer, then the impurity atoms are deposited as a layer on the first part. Finally, the semiconductor material is deposited again to form a second part of the intermediate layer. The second part of the intermediate layer is deposited, in particular, in such a way that it substantially completely covers the layer of impurity atoms and the first part of the intermediate layer.

The layer of impurity atoms is deposited, in particular, in such a way that it has openings. By way of example, the deposition of the impurity atoms is stopped before a closed layer is deposited. As an alternative, a closed layer of impurity atoms can first be produced and it can subsequently be removed again in places, for example, by an etching method such as reactive ion etching (RIE). In one configuration, the layer of impurity atoms, which in particular has openings, has a layer thickness of between 0.1 nm and 10 nm, preferably between 0.1 nm and 3 nm.

The second part of the intermediate layer is expediently deposited in such a way that it adjoins the first part of the intermediate layer in the region of the openings in the layer of impurity atoms. In particular, the layer thickness of the layer of impurity atoms is chosen such that the second part epitaxially overgrows the layer of impurity atoms.

Turning now to the drawings, similar or similarly acting constituent parts are provided with the same reference symbols. The drawings and the size relationships of the elements illustrated among one another should not be regarded as true to scale, unless dimensional units are explicitly specified. Rather, individual elements, for example, layers may be illustrated with an exaggerated size to be able to be better illustrated and/or for the sake of better understanding. The band structures and charge carrier densities are illustrated in a highly schematic and simplified manner.

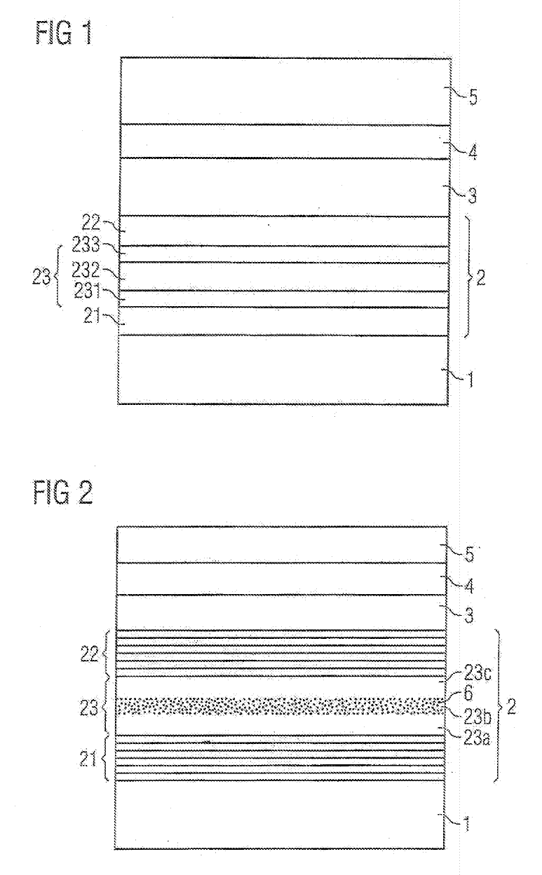

FIG. 1 shows a schematic sectional illustration through an optoelectronic semiconductor body in accordance with a first example. The semiconductor body is based on the semiconductor material AlInGaN, for example.

The optoelectronic semiconductor body has an n-conducting layer 1, a tunnel junction 2, a p-conducting layer 3, an active layer 4 and a further n-conducting layer 5, which succeed one another in this order.

The active layer 4 preferably has a pn junction, a double heterostructure, a single quantum well (SQW) or a multiple quantum well structure (MQW) for generating radiation. The designation quantum well structure does not constitute any significance with regard to the dimensionality of the quantization. It therefore encompasses, inter alia, quantum wells, quantum wires and quantum dots and any combination of these structures. Examples of MQW structures are described in WO 01/39282, U.S. Pat. No. 5,831,277, U.S. Pat. No. 6,172,382 B1 and U.S. Pat. No. 5,684,309, the contents of which are hereby incorporated by reference.

By way of example, the growth direction of the semiconductor body is directed from the n-conducting layer 1 to the p-conducting layer 3. The further n-conducting layer 5 succeeds the active layer 4 in the growth direction, while the p-conducting layer 3 precedes the active layer 4. In this way, the polarity of the optoelectronic semiconductor body is inverted in comparison with a semiconductor body without a tunnel junction 2. An advantageous orientation of piezoelectric fields in the semiconductor material is obtained in this way.

The tunnel junction has an n-type tunnel junction layer 21 facing the n-conducting layer 1. It furthermore has a p-type tunnel junction layer 22 facing the p-conducting layer 3. An intermediate layer 23 is arranged between the n-type tunnel junction layer 21 and the p-type tunnel junction layer 22.

In the course from the n-type tunnel junction layer 21 to the p-type tunnel junction layer 22, the intermediate layer 23 has an n-barrier layer 231, a middle layer 232 and a p-barrier layer 233.

By way of example, the n-conducting layer 1 is a GaN layer that is n-doped with silicon. The silicon is present, for example, in a concentration of between 1×10¹⁹ atoms/cm³ and 1×10²⁰ atoms/cm³ in the n-conducting layer. The p-conducting layer is, for example, likewise a GaN layer that is p-doped with magnesium, which is present in particular in a dopant concentration of between 1×10¹⁹ atoms/cm³ and 2×10²⁰ atoms/cm³ in the p-conducting layer 3. The limits of the specified ranges are in each case included here.

The n-type tunnel junction layer 21 is preferably an InGaN layer having, for example, an indium content of between 0 and 15 percent (0≦m≦0.15 in the formula AlₙInₘGa₁₋ₙ₋ₘN). It is likewise n-doped with silicon, for example, once again with a concentration of between 1×10¹⁹ atoms/cm³ and 1×10²⁰ atoms/cm³ inclusive. The p-type tunnel junction layer 22 is likewise an InGaN layer that contains, for example, between, inclusive, 0 percent and 30 percent indium. It is p-doped with magnesium, for example, in a concentration of 1×10¹⁹ atoms/cm³ to 3×10²⁰ atoms/cm³ inclusive.

The intermediate layer 23 is an AlInGaN layer, in particular an AlGaN layer. The aluminum content in the n-barrier layer 231 and in the p-barrier layer 233 is, for example, between 20 percent and 100 percent, inclusive of the limits. It is 80 percent. The aluminum content in the middle layer 232 is less than the aluminum content in the n-barrier layer 231 and less than the aluminum content in the p-barrier layer 233. In particular, the aluminum content is between 0 percent and 20 percent, inclusive of the limits.

In one example, the intermediate layer 23 is nominally undoped. As an alternative, the intermediate layer 23 can also be p-doped. By way of example, the n-barrier layer 231 and the p-barrier layer 233 each comprise magnesium as p-type dopant, and that in particular in a concentration of between 1×10¹⁹ atoms/cm³ and 5×10¹⁹ atoms/cm³ inclusive. In one configuration, the middle layer 232 is p-doped with magnesium in a concentration of between 0 and 2×10¹⁹ atoms/cm³, inclusive of the limits. The n-barrier layer 231 and the p-barrier layer 233 have, for example, a layer thickness of less than or equal to 1 nm. The middle layer 232 has, for example, a layer thickness of between 1 nm and 8 nm, inclusive of the limits. The n-barrier layer and the p-barrier layer each have an aluminum content of approximately 80 percent. The percentages relate to the n proportion in the material composition AlₙInₘGa₁₋ₙ₋ₘN.

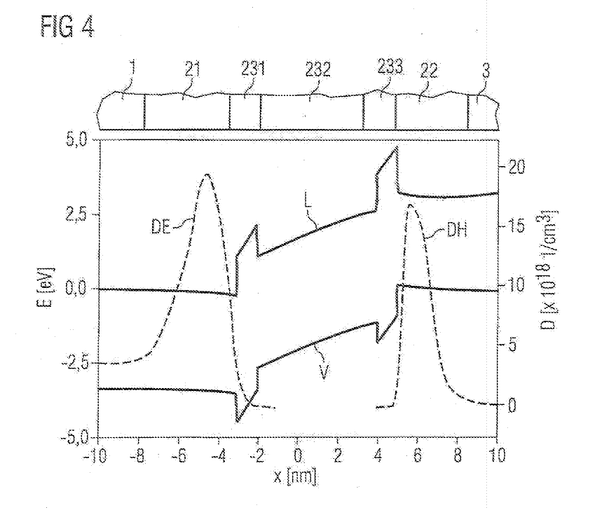

FIG. 4 schematically illustrates the band structure of the optoelectronic semiconductor body in accordance with FIG. 1. The energy E of the band edges of the conduction band L and of the valence band V are illustrated as a function of the position in the semiconductor body x. For the assignment of the x values to the layers of the optoelectronic semiconductor body, the latter are depicted in the upper region of the diagram.

The band gap of the semiconductor body is increased in the region of the n-barrier layer 231 and of the p-barrier layer 233 in comparison with the respectively adjoining layers. On account of the n-barrier layer 231 and on account of the p-barrier layer 233, strong polarization charges form, which lead to a particularly high charge carrier density and steep charge carrier density profiles in the n-type tunnel junction layer 221 and the p-type tunnel junction layer 22.

The charge carrier density D of the electrons DE and of the holes DH is likewise illustrated schematically in FIG. 4. On account of the high charge carrier densities DE, DH, a particularly high degree of lateral current spreading is obtained in the n-type tunnel junction layer 21 and the p-type tunnel junction layer 22. In addition, the band gap is smaller in the region of the middle layer 232 than in the region of the n-barrier layer 231 and the p-barrier layer 232 and the distance between the regions of high charge carrier density DE and DH is comparatively small. In this way, the tunnel junction has a particularly low electrical resistance. To put it another way, a high charge carrier density and a high tunneling probability can simultaneously be obtained by means of the barrier layers 231, 233 and the middle layer 232.

FIG. 2 shows a schematic sectional illustration of an optoelectronic semiconductor body in accordance with a second example. The semiconductor body in accordance with the second example differs from that of the first example in that both the n-type tunnel junction layer 21 and the p-type tunnel junction layer 22 are embodied as a superlattice composed of alternating layers having a different material composition and/or dopant concentration. n-type and/or p-type tunnel junction layers 21, 22 embodied as a superlattice are suitable for all configurations of the optoelectronic semiconductor body.

By way of example, the n-type tunnel junction layer 21 and/or the p-type tunnel junction layer 22 are embodied as a superlattice of alternating InGaN and GaN layers. In one development, the superlattice contains highly p-doped InGaN layers and nominally undoped GaN layers in the case of the p-type tunnel junction layer 22.

The layer thickness of the individual layers of the superlattice is preferably 2 nm or less, particularly preferably 1 nm or less. By way of example, the layer thickness is in each case 0.5 nm. The p-type tunnel junction layer 22 and/or the n-type tunnel junction layer 21 preferably has a thickness of 40 nm or less, particularly preferably of 20 nm or less. By way of example, the superlattice contains between five and 15 pairs of layers, inclusive of the limits; for example, the superlattice contains 10 pairs of layers.

A tunnel junction layer 21, 22 embodied as a superlattice advantageously has a particularly good morphology of the crystal structure. In particular, the morphology is improved in comparison with a highly doped individual layer. The multiplicity of interfaces contained in the superlattice structure reduces the risk of propagation of dislocations in the semiconductor body.

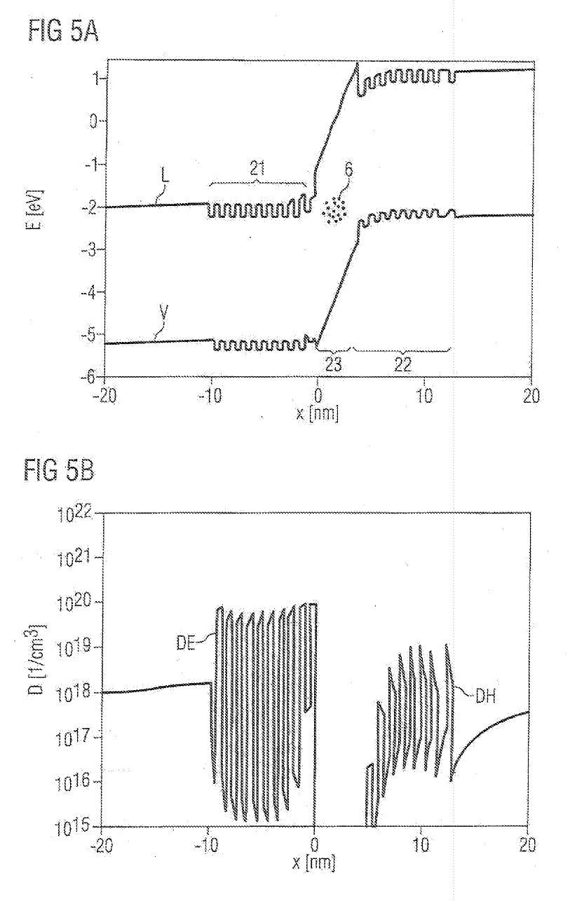

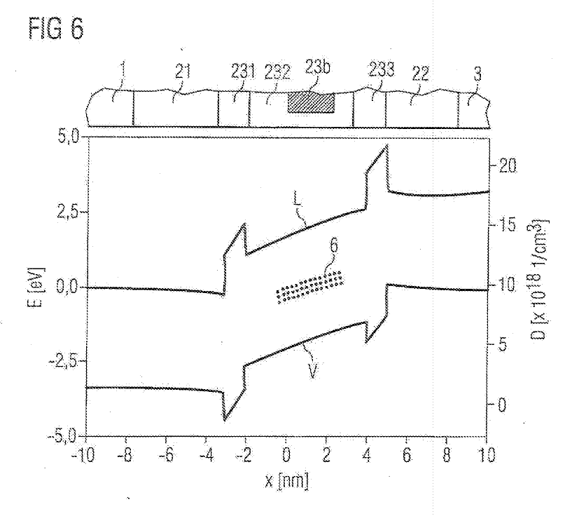

FIG. 5A schematically illustrates the band structure of the semiconductor body in accordance with the example from FIG. 2. The designations in FIG. 5A correspond to those in FIG. 4. FIG. 5B schematically shows the corresponding charge carrier density D of the electrons DE and holes DH.

The example of the n-type tunnel junction layer 21 and/or p-type tunnel junction layer 22 as a superlattice leads, in comparison with corresponding individual layers, to a further increase in the charge carrier concentration in the tunnel junction layers and thus to an improvement in the current spreading.

A further difference between the optoelectronic semiconductor body in accordance with the second example and the optoelectronic semiconductor body in accordance with the first example is that the intermediate layer 23 is provided with imperfections 6 in a targeted manner. The intermediate layer 23 contains no n-barrier layer and no p-barrier layer such as have been described in connection with the first example. However, such n-type and p-barrier layers are also suitable for the second example.

The intermediate layer 23 is provided with the imperfections 6 in a central region 23b, while the region 23a that adjoins or is adjacent to the n-type tunnel junction layer 21 and also the region 23c of the intermediate layer 23 that adjoins or is adjacent to the p-type tunnel junction layer 22 are not provided with the imperfections 6 in a targeted manner, that is to say, in particular, are free of the imperfections 6.

During the production of the optoelectronic semiconductor body, in particular the intermediate layer 23 is produced by deposition of a semiconductor material, in particular of AlInGaN or GaN, in an epitaxy reactor. In accordance with a first configuration, during the deposition of the central region 23b, hydrogen gas is conducted into the epitaxy reactor. By means of the hydrogen gas, during the epitaxial deposition of the central region 23b of the intermediate layer 23, defects are produced in the semiconductor material in a targeted manner, the defects constituting the imperfections 6.

By way of example, the hydrogen gas is conducted into the epitaxy reactor in an amount of six standard cubic centimeters per minute. The time duration for which the hydrogen gas is conducted into the epitaxy reactor is preferably two minutes or less, particularly preferably one minute or less.

In an alternative configuration, the defects 6 are produced by greatly altering the process temperature and/or the pressure in the epitaxy reactor during the deposition of the central region for a time duration of, for example, 120 seconds or less. A great alteration is understood to mean, for example, an alteration of the pressure by 100 millibars per minute or more and/or of the temperature by 60 kelvins per minute or more. The change can take place in steps or continuously, as a so-called “temperature or pressure ramp.”

As a further alternative, the imperfections 6 can also be produced by depositing impurity atoms in addition to the semiconductor material during the epitaxial growth of the central region 23b. The impurity atoms are, for example, at least one metal, at least one transition metal and/or at least one rare earth element. The deposition of a combination of a plurality of metals, transition metals and/or rare earths is also conceivable. By way of example, bromine, iron and/or manganese are suitable as impurity atoms.

In contrast to customary p-type dopants or n-type dopants such as magnesium or silicon, such impurity atoms have the advantage that they generate electronic states that are arranged energetically approximately in the center of the band gap of the intermediate layer 23. This is illustrated schematically in FIG. 5A. The tunneling current of the tunnel junction 2 advantageously increases more than proportionally with the concentration of the impurity atoms 6.

The impurity atoms are present, for example, in a concentration of greater than or equal to 10¹⁵ atoms/cm³. The concentration is particularly preferably less than or equal to 10¹⁹ atoms/cm³ since the risk of impairment of the morphology of the intermediate layer 23 increases above such a concentration. Impurity atoms deposited during the epitaxial growth of the semiconductor material are incorporated, in particular, into the crystal lattice of the semiconductor material. As an alternative, the impurity atoms and the semiconductor material can also be deposited successively. This is explained below in connection with the third example.

The deep imperfections or “midgap states” that are brought about by the impurity atoms 6 advantageously make it easier for the charge carriers to tunnel through the intermediate layer 23. In this way, the efficiency of the tunnel junction 2 is improved by comparison with a tunnel junction without imperfections introduced in a targeted manner.

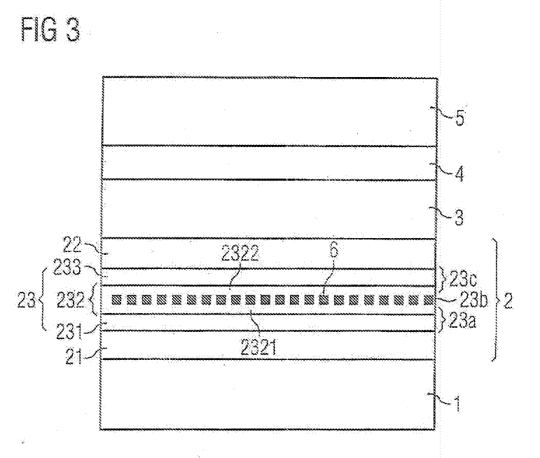

FIG. 3 shows a schematic cross section through an optoelectronic semiconductor body in accordance with a third example. The optoelectronic semiconductor body in accordance with the third example corresponds to that of the first example. In addition, however, the middle layer 232 of the intermediate layer 23 is provided with imperfections 6 in a targeted manner such as have been described in connection with the second example. The imperfections 6 are impurity atoms introduced as a layer into the middle layer 232.

During the production of the semiconductor body, in contrast to the production methods described in connection with the second example, a first part 2321 of the middle layer 232 is first deposited on the n-barrier layer 231. Afterward, the layer of impurity atoms 6 is deposited. Finally, a second part of the intermediate layer 2322 is deposited on the impurity atoms 6 and the first part 2321. Afterward, the intermediate layer 23 is completed by the deposition of the p-barrier layer 233.

The layer of impurity atoms 6 is produced in such a way that it has openings. To put it another way, the first part 2321 of the middle layer 232 is covered by the impurity atoms 6 in places and is not covered by the impurity atoms 6 in places. The second part 2322 of the middle layer 232 is then deposited in such a way that, in the region of the openings in the layer of impurity atoms 6, that is to say where the first part 2321 is not covered by impurity atoms 6, the second part adjoins the latter. For this purpose, the layer thickness of the layer of impurity atoms 6 is expediently chosen such that the layer of impurity atoms 6 can be epitaxially overgrown. In one configuration, the layer of impurity atoms 6 is a non-closed monolayer. However, larger layer thicknesses are also conceivable. By way of example, the layer of impurity atoms 6 has a layer thickness of between 0.1 nm and 10 nm, preferably between 0.1 nm and 3 nm, in each case inclusive of the limits.

In this example, the central region 23b of the intermediate layer 23 that is provided with imperfections 6 corresponds to the layer of impurity atoms 6. The barrier layers 231, 233 and also partial regions of the middle layer 232 which precede and respectively succeed the central region 23b are free of the impurity atoms. The production methods mentioned in connection with the second example are also suitable for producing the central region 23b of the intermediate layer 23 that is provided with imperfections 6. Conversely, a layer of impurity atoms 6 and the production method such as have been described in connection with this example are also suitable for the second example.

This disclosure is not restricted to the example or by the description on the basis thereof. Rather, the disclosure encompasses any novel feature and also any combination of features, which in particular includes any combination of features in the appended claims and examples, even if this feature or this combination itself is not explicitly specified in the claims or examples.

1-15. (canceled)

16. An optoelectronic semiconductor body comprising an epitaxial semiconductor layer sequence comprising:
a tunnel junction comprising an intermediate layer between an n-type tunnel junction layer and a p-type tunnel junction layer, wherein the intermediate layer has an n-barrier layer facing the n-type tunnel junction layer, a p-barrier layer facing the p-type tunnel junction layer, and a middle layer with a material composition differing from material compositions of the n-barrier layer and the p-barrier layer; and
an active layer that emits electromagnetic radiation.

17. The optoelectronic semiconductor body of claim 16, wherein the n-barrier layer, the middle layer and the p-barrier layer comprise a semiconductor material which contains a first and a second component, wherein a proportion of the first component is smaller in the middle layer than in the n-barrier layer and the p-barrier layer.

18. The optoelectronic semiconductor body of claim 17, wherein the first component contains or consists of aluminum and the second component contains at least one element selected from the group consisting of In, Ga, N and P.

19. The optoelectronic semiconductor body of claim 17, wherein a proportion of the first component is less than or equal to 20% in the middle layer and is greater than or equal to 20% in the n-barrier layer and the p-barrier layer.

20. The optoelectronic semiconductor body of claim 16, wherein a layer thickness of the n-barrier layer and/or of the p-barrier layer is less than or equal to 2 nm.

21. An optoelectronic semiconductor body comprising an epitaxial semiconductor layer sequence comprising:
a tunnel junction comprising an intermediate layer between an n-type tunnel junction layer and a p-type tunnel junction layer, wherein the intermediate layer is provided with imperfections in a targeted manner; and
an active layer that emits electromagnetic radiation.

22. The optoelectronic semiconductor body of claim 16, wherein the intermediate layer is provided with imperfections in a targeted manner in a region of the middle layer.

23. The optoelectronic semiconductor body of claim 21, wherein the imperfections are formed at least in part by defects of a semiconductor material of the intermediate layer.

24. The optoelectronic semiconductor body of claim 21, wherein the imperfections are formed at least in part by impurity atoms incorporated into a crystal lattice of a semiconductor material of the intermediate layer, and/or wherein the impurity atoms are contained as a layer in the intermediate layer.

25. The optoelectronic semiconductor body of claim 21, wherein the imperfections are formed at least in part by impurity atoms contained as a layer in the intermediate layer and the layer of impurity atoms has openings pervaded by the semiconductor material.

26. The optoelectronic semiconductor body of claim 16, wherein the n-type tunnel junction layer and/or the p-type tunnel junction layer are/is formed as a superlattice of alternating layers.

27. A method for producing an optoelectronic semiconductor body comprising an epitaxial semiconductor layer sequence comprising a tunnel junction comprising an n-type tunnel junction layer, an intermediate layer and a p-type tunnel junction layer; and an active layer that emits electromagnetic radiation, comprising:
producing the intermediate layer by epitaxially depositing a semiconductor material; and
providing imperfections in the intermediate layer in a targeted manner in selected locations.

28. The method of claim 27, wherein providing the imperfections comprises introducing defects into the semiconductor material, wherein, during deposition of the semiconductor material in an epitaxy reactor, hydrogen gas is conducted into the epitaxy reactor at selected times.

29. The method of claim 27, wherein providing imperfections comprises introducing defects into the semiconductor material, wherein, during deposition of the semiconductor material in an epitaxy reactor, temperature and/or pressure in the epitaxy reactor are/is altered.

30. The method of claim 27, wherein providing imperfections comprises introducing impurity atoms into the intermediate layer.

31. The optoelectronic semiconductor body of claim 18, wherein a proportion of the first component is less than or equal to 20% in the middle layer and is greater than or equal to 20% in the n-barrier layer and the p-barrier layer.

32. The optoelectronic semiconductor body of claim 17, wherein a layer thickness of the n-barrier layer and/or of the p-barrier layer is less than or equal to 2 nm.

33. The optoelectronic semiconductor body of claim 18, wherein a layer thickness of the n-barrier layer and/or of the p-barrier layer is less than or equal to 2 nm.

34. The optoelectronic semiconductor body of claim 19, wherein a layer thickness of the n-barrier layer and/or of the p-barrier layer is less than or equal to 2 nm.

35. The optoelectronic semiconductor body of claim 22, wherein the imperfections are formed at least in part by defects of a semiconductor material of the intermediate layer.
